(19) United States
(12) Patent Application Publication
(10) Pub. No.: US 2004/0209196 A1
(43) Pub. Date: Oct. 21, 2004

(54) [MICROLITHOGRAPHIC PROCESS]

(76) Inventors: MENG-WEI CHEN, Hsinchu (TW); TA-HUNG YANG, Hsinchu (TW); CHING-YU CHANG, YILAN HSIEN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,833

(22) Filed: May 12, 2003

(30) Foreign Application Priority Data
Apr. 18, 2003 (TW) 92109020

(51) Int. Cl. G03F 7/20

(52) U.S. Cl. 430/320; 430/394; 430/396; 430/311

(57) ABSTRACT

A microlithographic process is provided. First, a photoresist layer is formed over a substrate. Thereafter, a first photomask having a dense pattern thereon is set up over the photoresist layer. A first photo-exposure is carried out to transfer the dense pattern on the first photomask onto the photoresist layer. The first photo-exposure is performed using a beam of light at an energy level E1. The first photomask is removed and then a second photomask having a sparse pattern thereon is set up over the photoresist layer. A second photo-exposure is carried out to transfer the sparse pattern on the second photomask onto the photoresist layer. The second photo-exposure is performed using a beam of light at an energy level E2 such that E2 is greater than E1. Finally, the photoresist layer is chemically developed to produce a patterned photoresist layer.

### BACKGROUND OF INVENTION

1. Field of Invention

The present invention relates to a microlithographic process. More particularly, the present invention relates to a microlithographic process that involves assigning patterns each of which possesses a unique density to different masks to prevent any deviation of critical dimensions between the patterns with different densities.

2. Description of Related Art

As the level of integration of integrated circuits increases, the dimension of each circuit device is reduced correspondingly. In the fabrication of semiconductors, microlithography is a core technique for producing various metal-oxide-semiconductor structures. For example, by performing microlithographic processes, patterned films and doped regions are formed over a substrate.

In a microlithography, patterns are transferred through photo-exposure processes. Due to a difference in exposure intensity between the sparse pattern region and the dense pattern region on a photomask, the so-called flare effect frequently occurs. In other words, the intensity of light passing through the sparse pattern regions is generally weaker than the intensity of light passing through the dense pattern regions when the sparse pattern region and the dense pattern region are on the same mask. This often leads to considerabley deviation in the critical dimension between the dense pattern region and the sparse pattern region. The dense pattern region always receives a higher dosage of light energy compared with the sparse pattern region so that the critical dimension will differ between patterns with different densities.

To reduce critical dimension deviation between a dense pattern region and a sparse pattern region, an additional filter is often deployed in the photo-exposure station so that the light energy going to the sparse pattern region and the dense pattern region will differ. However, to implement the conventional method, each photo-exposure station must have a filtering plate. Furthermore, a different filtering plate must be used to match each design pattern, which is highly inconvenient.

### SUMMARY OF INVENTION

Accordingly, one object of the present invention is to provide a microlithographic process capable of reducing the deviation in critical dimension between regions having a different pattern densities due to optical flare occurring in a photo-exposure operation.

A second object of this invention is to provide a microlithographic process capable of eliminating the complicated steps when a filtering plate is used to reduce the light intensity going to the sparse pattern region in a conventional method.

To achieve these and other advantages and in accordance with the purpose of the invention, as embodied and broadly described herein, the invention provides a microlithographic process. First, a photoresist layer is formed over a substrate. Thereafter, a first photomask having a dense pattern thereon is set up over the photoresist layer. A first photo-exposure is carried out to transfer the dense pattern on the first photomask onto the photoresist layer. The first photo-exposure is performed using a beam of light at an energy level E1. The first photomask is removed and then a second photomask having a sparse pattern thereon is set up over the photoresist layer. A second photo-exposure is carried out to transfer the sparse pattern on the second photomask onto the photoresist layer. The second photo-exposure is performed using a beam of light at an energy level E2 such that E2 is greater than E1. Finally, the photoresist layer is chemically developed to produce a patterned photoresist layer. The patterned photoresist layer comprises a dense pattern and a sparse pattern both having a standard critical dimension with very little deviation.

In this invention, the dense pattern and the sparse pattern are separately designed and fabricated on two different masks. Furthermore, light intensity optimized for exposing the mask with a given pattern density is used to perform each photo-exposure operation. Hence, any deviation in critical dimension between a dense pattern region and a sparse pattern region is minimized.

In this invention, flaring is minimized due to the assignment of different density patterns to different masks. In addition, setting up masks each having a different density pattern thereon is simpler than setting up a filtering plate in the photo-exposure station in a conventional method.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1C are schematic cross-sectional views showing the steps in a microlithographic process according to one preferred embodiment of this invention.

FIG. 2 is a top view of a first photomask according to one preferred embodiment of this invention.

FIG. 3 is a top view of a second photomask according to one preferred embodiment of this invention.

FIG. 4 is a top view of a patterned photoresist layer fabricated according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

In this invention, patterns having a different density are assigned to different masks to prevent any deviation in critical dimension caused by flaring. Furthermore, light intensity optimized for exposing the mask with a given pattern density is used to perform each photo-exposure operation. Ultimately, the patterned photoresist layer has critical dimensions that deviate very little between a dense pattern region and a sparse pattern region. In the following, a preferred embodiment is selected to describe the invention.

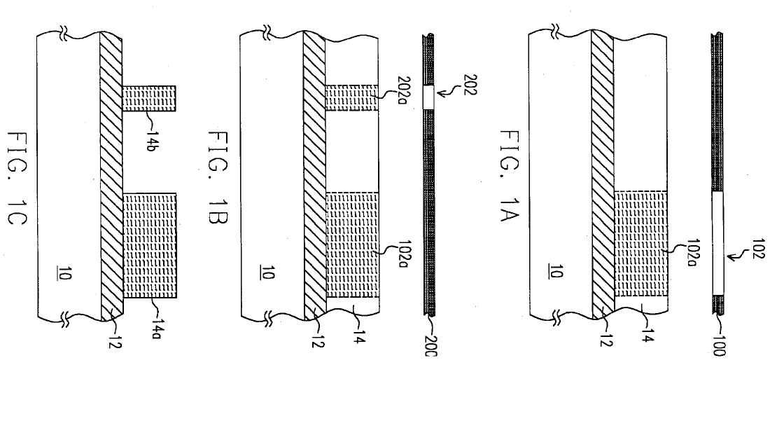

FIGS. 1A to 1C are schematic cross-sectional views showing the steps in a microlithographic process according to one preferred embodiment of this invention. As shown in FIG. 1A, a substrate 10 with a material layer 12 thereon is provided. To pattern the material layer 12, a patterned photoresist layer is typically formed over the material layer 12 to serve as an etching mask. The material layer 12 can be a conductive layer or a non-conductive layer, for example.

A photoresist layer 14 is formed over the material layer 12. The photoresist layer 14 is formed, for example, by spin-coating a layer of photoresist substance over the material layer 12 and then soft baking the photoresist substance to remove any solvent within the photoresist substance.

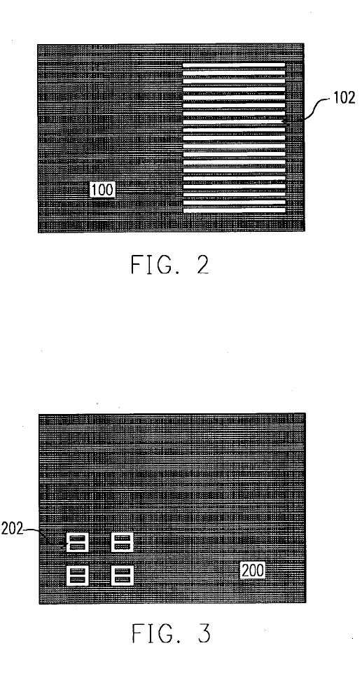

A photomask 100 is set up over the photoresist layer 14. The photomask 100 has a dense pattern 12 thereon as shown in FIG. 2. FIG. 2 is a top view of a first photomask according to one preferred embodiment of this invention. In one embodiment, the dense pattern 102 is the memory cell array of a memory device, for example. The dense pattern 102 on the photomask 100 is a transparent region and the areas outside the dense pattern 102 are opaque regions, for example.

Thereafter, a first photo-exposure is carried out to transfer the dense pattern 102 on the photomask 100 to the photoresist layer 14. Thus, an image 102a of the dense pattern is formed in the photoresist layer 14. The first photo-exposure is performed with the light intensity set at an energy level E1. In general, the light energy level E1 used for performing the first photo-exposure is optimized according to the density and size parameters of the dense pattern 102 on the photomask 100.

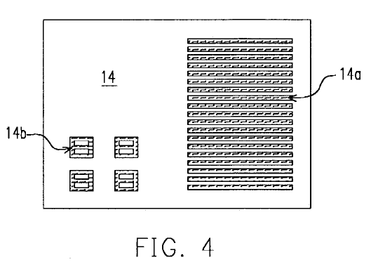

As shown in FIG. 1B, the photomask 100 is removed and then another photomask 200 is set up over the photoresist layer 14. The photomask 200 has a sparse pattern 202 as shown in FIG. 3. FIG. 3 is a top view of a second photomask according to one preferred embodiment of this invention. In one embodiment of this invention, the sparse pattern 202 is a peripheral circuit pattern of a memory device, for example. The sparse pattern 202 on the photomask 200 is a transparent region and the areas outside the sparse pattern 202 are opaque regions, for example.

Thereafter, a second photo-exposure is carried out to transfer the sparse pattern 202 on the photomask 200 to the photoresist layer 14. Thus, an image 202a of the sparse pattern is formed in the photoresist layer 14. The second photo-exposure is performed with the light intensity set to an energy level E2. In general, the light energy level E2 used for performing the second photo-exposure is optimized according to the density and size parameters of the sparse pattern 202 on the photomask 200.

Note that when a photo-exposure process is performed to transfer dense patterns and sparse patterns from a photomask to a photoresist layer, the intensity of light passing through the sparse pattern regions is generally weaker than the intensity of light passing through the dense pattern regions. Therefore, in the aforementioned first photo-exposure and second photo-exposure, the energy level E2 (used in the second photo-exposure for transferring the sparse pattern) is higher than the energy level E1 (used in the first photo-exposure for transferring the dense pattern).

As shown in FIG. 1C, the patterned photoresist layer 14 is chemically developed to form a dense photoresist pattern 14a and a sparse photoresist pattern 14b as shown in FIG. 4. FIG. 4 is a top view of a patterned photoresist layer fabricated according to one preferred embodiment of this invention. Thereafter, using the patterned photoresist layer 14 as an etching mask, the material layer 12 is patterned.

In the aforementioned embodiment, the patterned photoresist layer is used as an etching mask for patterning the material layer. However, the microlithographic process provided according to this invention is not limited to the above application. The microlithographic process can be applied to other fabrication processes including, for example, the patterning of a photoresist layer to serve as a mask in an ion implantation.

In conclusion, major advantages of this invention include: 1. The dense pattern and the sparse pattern are separately designed and fabricated on two different masks. Furthermore, light intensity optimized for exposing the mask with a given pattern density is used to perform each photo-exposure operation. Hence, any deviation in critical dimension between a dense pattern region and a sparse pattern region is minimized. 2. Flaring is minimized due to the assignment of different density patterns to different masks. In addition, the setting of masks each having a different density pattern thereon is simpler than the setting of a filtering plate in the photo-exposure station in a conventional method.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A microlithographic process, comprising the steps of:
providing a photoresist layer;
setting a first photomask over the photoresist layer, wherein the first photomask has a dense pattern thereon;
performing a first photo-exposure to transfer the dense pattern on the first photomask to the photoresist layer, wherein the first photo-exposure is carried out using a beam of light at an energy level E1;
removing the first photomask;
setting a second photomask over the photoresist layer, wherein the second photomask has a sparse pattern thereon;
performing a second photo-exposure to transfer the sparse pattern on the second photomask to the photoresist layer, wherein the second photo-exposure is carried out using a beam of light at an energy level E2 not equal to E1; and
performing a chemical development to produce a patterned photoresist layer.

2. The microlithographic process of claim 1, wherein the dense pattern comprises a memory cell array pattern.

3. The microlithographic process of claim 1, wherein the sparse pattern comprises a peripheral circuit pattern.

4. The microlithographic process of claim 1, wherein the light intensity level E1 for performing the first photo-exposure is an optimized energy level for transferring the dense pattern.

5. The microlithographic process of claim 1, wherein the light intensity level E2 for performing the second photo-exposure is an optimized energy level for transferring the sparse pattern.

6. The microlithographic process of claim 1, wherein the light intensity level E1 for performing the first photo-exposure is smaller than the light intensity level E2 for performing the second photo-exposure.

7. The microlithographic process of claim 1, wherein the dense pattern on the first photomask comprises a transparent region.

8. The microlithographic process of claim 1, wherein the sparse pattern on the second photomask comprises a transparent region.

9. A method of designing photomask comprising the steps of:
assigning the dense pattern of a film to a first photomask; and
assigning the sparse pattern of the film to a second photomask.

10. The method of claim 9, wherein the dense pattern comprises a memory cell pattern.

11. The method of claim 9, wherein the sparse pattern comprises a peripheral circuit pattern.

12. The method of claim 9, wherein the dense pattern on the first photomask comprises a transparent region.

13. The method of claim 9, wherein the sparse pattern on the second photomask comprises a transparent region.
